(19) United States
(12) Patent Application Publication
(10) Pub. No.: US 2025/0330028 A1
(43) Pub. Date: Oct. 23, 2025

(54) A DEVICE, AND CORRESPONDING METHOD, FOR CELL BALANCING IN AN ELECTRIC BATTERY SYSTEM

(71) Applicant: DUKOSI LIMITED, Edinburgh (GB)

(72) Inventors: Simon QUINN, Edinburgh (GB); Gavin MCVEIGH, Edinburgh (GB); Joel SYLVESTER, Edinburgh (GB); Ross BALLANY, Edingburgh (GB); Doug CAMERON, Edinburgh (GB); Andrew BREWSTER, Edinburgh (GB); Mohammed BUHARI, Edinburgh (GB); Anders CONVREY, Edinburgh (GB)

(21) Appl. No.: 18/869,759

(22) PCT Filed: May 26, 2023
(86) PCT No.: PCT/EP2023/064255

§ 371 Date: Nov. 26, 2024

(30) Foreign Application Priority Data
May 27, 2022 (EP) 22175864.2

(51) Int. Cl. H02J 7/00; G01R 31/3842; G01R 31/389; G01R 31/392

(52) U.S. Cl. CPC H02J 7/0016; G01R 31/3842; G01R 31/389; G01R 31/392; H02J 7/00036; H02J 7/0019; H02J 7/0048; H02J 7/005; H02J 7/00714; H02J 7/007182

(57) ABSTRACT

The present disclosure relates to a battery pack of an electric battery system, for balancing individual cells within the battery pack with respect to voltage, charge and/or state of charge. The electric battery system comprises at least one pack, each pack comprising a plurality of battery cells, and each battery cell is monitored via a cell monitoring device (CMD), which provides cell-level measurements. Cell balancing is provided in a manner which allows for the simultaneous measuring of a cell-level balancing current and a cell-level balancing voltage during the balancing. Such measuring allows for control of the cell balancing without having to continuously interrupt and restart the cell balancing procedure.

### BACKGROUND

Battery systems, comprising a plurality of battery cells, are used in a wide range of modern electric power applications. For example, they are used to power electric vehicles, they are used in industrial power applications, in transportation, and in commercial applications such as powering of modern electronic devices. Given the relatively high-power demands of such applications, a battery system often comprises a plurality of battery cells coupled together to achieve the required power output. The battery cells may be coupled together to form a battery pack, and the battery system may comprise one or more battery packs.

The individual cells in a battery pack may comprise different capacities, which may also vary over time due to different rates of degradation, and therefore over the course of multiple charge and discharge cycles, the cells may comprise a different state of charge. State of charge (SOC) is defined as the ratio of the available capacity and the maximum possible charge that may be stored in a battery cell. Balancing the cells of a multiple cell battery pack may assist in improving the capacity and life of the battery pack by maintaining an equivalent (or balanced) state of charge level at each cell within the pack.

### SUMMARY

Current means of cell balancing do not allow for obtaining measurements useful to the monitoring and control of the cell balancing during the balancing itself. Therefore, current means of balancing require the balancing procedure to be stopped periodically in order to obtain cell-level measurements related to, for example, state of charge, cell-level balancing voltage and/or cell-level balancing current. Thus, the example embodiments presented herein provide a means of cell balancing in which measurements useful in controlling the balancing procedure may be obtained without interrupting the balancing procedure.

Accordingly, the example embodiments are directed towards a battery pack comprising a plurality of cell monitoring devices (CMDs) for balancing cells within the battery pack with respect to voltage, charge and/or state of charge. The battery pack comprises a plurality of battery cells, wherein each battery cell is monitored via a respective cell monitoring device (CMD) which provides cell-level measurements. Each CMD comprises a first measuring unit comprising at least one sensor configured to obtain a cell-level voltage measurement and/or a cell-level charge measurement of the respective cell. Each CMD further comprises a balance control unit configured to identify a respective cell for cell balancing based on the measured cell-level voltage, the measured cell-level charge and/or a determined state of charge of the respective cell. The balance control unit is further configured to balance passively the respective cell upon discharging or charging of the battery pack. Each CMD further comprises a second measuring unit configured to measure a cell-level balancing current of the respective cell during the cell balancing and the balance control unit further configured to control the cell balancing of the respective cell based on at least one of the measured cell-level balancing current, the measured cell-level voltage or the measured cell-level charge. In controlling the balancing process, each CMD is further configured to determine the internal resistance value of the battery cell to which the CMD is connected.

The example embodiments are also directed towards a method, in a battery pack of an electric battery system, for balancing cells within the battery pack with respect to voltage, charge and/or state of charge. The electric battery system comprises at least one pack, each pack comprising a plurality of battery cells, wherein each battery cell is monitored via a cell monitoring device (CMD) which provides cell-level measurements. The method comprises measuring continuously, with at least one sensor comprised in a respective CMD, at least one of a cell-level voltage or a cell-level charge of the respective cell. The method also comprises identifying at least one cell of the plurality of battery cells to undergo cell balancing based on at least one of the respective measured cell-level voltage, the measured cell-level charge or a determined cell-level state of charge. The method further comprises balancing passively the at least one identified cell of the battery pack upon charging or discharging of the pack of the at least one identified cell. The method additionally comprises measuring a cell-level balancing current of the at least one identified cell during the balancing, and controlling the balancing of the at least one identified cell based on at least one of the measured cell-level balancing current, the measured cell-level voltage or the measured cell-level charge.

The example embodiments are also directed towards a method, in a battery pack in a battery pack of an electric battery system, for determining battery cell internal resistance values, wherein the electric battery system comprises at least one pack, each pack comprising a plurality of battery cells, wherein each battery cell is characterized by an internal resistance value and monitored via a cell monitoring device, CMD, which provides cell-level measurements. The method comprises performing one or more measurement cycles on at least one battery cell. The measurement cycle comprises the steps of: activating a balancing process; measuring a cell-level balancing current and a cell-level voltage before and after activating the balancing process; deactivating the balancing process after a first predetermined period of time; measuring the cell-level balancing current and the cell-level voltage before and after deactivating the balancing process; and, waiting a second predetermined period of time. The method also comprises determining the internal resistance value of the at least one battery cell based on the measured cell-level balancing current and the cell-level voltage during the one or more measurement cycles.

The example embodiments also comprise a computer-readable medium storing instructions which, when executed by a processor of a respective CMD of a batter pack, cause the respective CMD to execute the method described above.

### BRIEF DESCRIPTION OF THE DRAWINGS

The foregoing will be described in more detail with the following more particular description of the example embodiments, as illustrated in the accompanying drawings in which reference characters refer to the same parts throughout the different views. The drawings are not necessarily to scale, emphasis instead being placed upon illustrating the example embodiments.

FIG. 1 is a schematic of an electric battery system;

FIG. 2 is a graph illustrating the relationship between open circuit voltage and state of charge associated with a battery cell;

FIG. 3 is a schematic of the electric battery system of FIG. 1 featuring a multiplexed input;

FIG. 4 is a schematic of an electric battery system, according to the example embodiments presented herein;

FIG. 5 is an illustration of an example Cell Monitoring Device (CMD) of FIG. 4, according to some of the example embodiments presented herein;

FIG. 6 is an illustration of another example CMD, featuring a kelvin connection, of FIG. 4, according to some of the example embodiments presented herein;

FIG. 7 is a flow diagram depicting operation steps taken by CMD(s) of FIGS. 4-6, according to some of the example embodiments presented herein;

FIGS. 8 and 9 are graphs depicting the relationship of cell voltage over time during a cell balancing procedure, according to some of the example embodiments presented herein;

FIG. 10 is an illustration of another example CMD, featuring an internal resistance of the attached battery cell, according to some of the example embodiments presented herein;

FIG. 11 is a graph depicting the evolution of cell voltage and balancing current overtime during measurement of the internal resistance of a battery cell, according to some of the example embodiments presented herein;

FIG. 12 is a graph illustrating characteristic changes in the internal resistance of a battery cell as a function of the state of charge and age of the cell, according to some of the example embodiments presented herein; and

FIG. 13 is a graph illustrating characteristic changes in the internal resistance of a battery cell as a function of the cell temperature, according to some of the example embodiments presented herein.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims.

A battery system typically comprises multiple cells wired in a configuration to provide the desired battery system voltage and capacity and additional parts necessary for the safe operation of the cells and transfer of energy to/from the cells. A cell is the basic unit of any battery system. The defining characteristic of a cell is its electrochemical characteristics. For a particular cell chemistry, there is a minimum, typical and maximum voltage that is determined by the electrochemistry of the system, rather than the configuration of the system. These voltages cannot be varied other than by changing the electrochemical state of the cell. Cells may be wired in parallel, to increase the overall capacity, but these paralleled cells can simply be regarded from a cell monitoring perspective as a larger single cell since they still have the same voltage characteristics as determined by the electrochemistry.

Cells can also be wired in series. The series stack of cells has a voltage primarily determined by the stack configuration. The stack voltage will be the sum of the cell voltages. The stack voltage can be varied by adding or removing cells without changing their electrochemical state. Typically, the stack of cells will be charged and discharged, with their electrochemical state changing in tandem. Each cell must be monitored to ensure it stays within its safe operating range. This is the job of the cell monitoring device (CMD). CMDs provide cell-level measurements such that separate measurements are taken on individual cells and the information obtained is with respect to an individual cell.

A battery pack consists of multiple cells in series. The battery pack provides the full battery system voltage. Multiple battery packs may be wired in parallel to increase the battery system capacity, but not in series. The cells may be grouped into modules. The defining characteristic of a module is its physical configuration, for example, the number and connectivity between a number of cells. A module may comprise of any number of cells. A module comprises of two or more cells, or an entire pack. In the case of there being only a single pack in the battery system, then a module could encompass an entire battery system.

More often though, a pack is configured as multiple modules, where each module is configured from multiple cells in series. Multiple modules are then wired in series, or in parallel and in series. Modules that are configured to provide the full the battery system voltage and are wired in parallel may be considered as packs. A module has a defined size, shape and is typically packaged in an enclosure of some kind.

The module configuration is driven by the physical requirements of the battery pack. Often a module is configured to have a low enough voltage that it can be handled without there being an electrical shock hazard. Often a module is configured for a number of cells that matches the number of voltage sensor inputs on a cell monitoring device. A very common example is a twelve cell monitoring device. A module then consists of twelve cells and a connection to a cell monitoring device. In many battery packs, the properties of the CMD define the configuration of a module, and the battery pack is then built from multiple such modules.

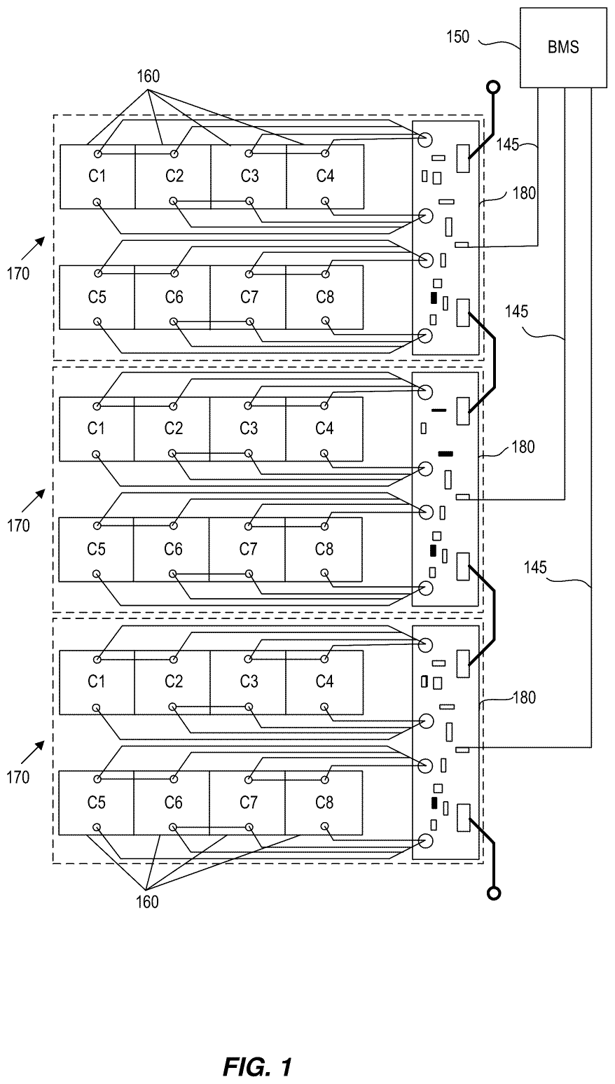

FIG. 1 illustrates a known prior art system. The battery system of FIG. 1 comprises three battery modules 170, with each battery module comprising eight battery cells (C1-C8) 160. Each battery cell C1-C8, within each battery module 170, is hardwired to a respective CMD 180. The position of each cell C1-C8 within battery module 170 may be mapped during assembly of battery module 170. In use, CMD 180 receives measurement data from each one of cells C1-C8, and can determine the source of the received measurement data based on the pre-defined cell mapping information. CMDs 180 illustrated in FIG. 1 are connected in a star topology. Alternatively, each CMD 180 may be connected to Battery Management System (BMS) via a series daisy chain connection. A star topology is advantageous since there is no communication hierarchy imposed on BMS 150, and instead, communication with each CMD 180 is by direct wired connection without use of any proxies.

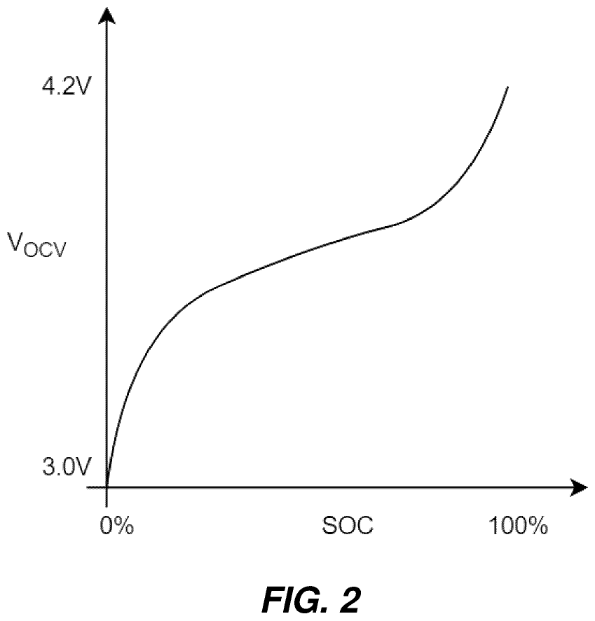

A battery pack consisting of multiple lithium ion cells will, over time, go out of balance. At manufacture, every cell will be at the exact same state of charge (SOC) when it is assembled into a pack, as indicated by every cell having the exact same voltage across the cells terminals (the terminal voltage). This may be 100% SOC, or a lower (safer) level such as 30% SOC. Alternatively, the cells may all be at the exact same terminal voltage. State of Charge SOC is directly mapped to the cell terminal open circuit voltage. FIG. 2 illustrates the function relating SOC to the open circuit voltage V_{ocv}, and the function is highly non-linear, and the terminal voltage (Vₜₑᵣₘ) only equals V_{ocv} when the current is zero and the cell is rested.

If all battery cells were ideal, then as the pack is charged and discharged the terminal voltage and SOC for all the cells would track each other. In practice though, every cell will have manufacturing variations (capacity variance, resistance variance) and small operating condition variations. An example variance is the cell temperature, where it is not unusual to see a 5° C. variation in cell operating temperature across a pack.

Every cell has a small self discharge current. Left alone, a cell will slowly discharge without any external load. This process may take many months or even years. The self-discharge current is always present, but is usually only measurable when the cell is otherwise not being charged or discharged, and only then over very long periods of time. The self-discharge current may be higher at high temperatures and lower at low temperatures. The self-discharge current may also depend on the manufacturing variations as well. Over months or years, due to the differences in self discharge current seen by each cell, a pack will go out of balance. Cells that have a large self discharge current will be sitting at a lower voltage than cells that see a smaller self discharge current.

When a pack is charged, the charging process must stop as soon as the first cell reaches its maximum allowable voltage Vₘₐₓ. To continue to charge beyond this point may lead to damage to the cell. However, because all cells are in series, if charging stops for one cell, it stops for all cells. Thus, any cell at a lower voltage, or SOC, will not be fully charged. Similarly, when a pack is discharged, the discharge process must stop as soon as the first cell reaches its allowable minimum voltage Vₘᵢₙ. Any cell at a higher voltage or SOC will not be fully discharged.

Thus, the pack capacity is determined by the charge that will take a pack from the state where a single cell that happens to have the highest voltage is sitting at Vₘₐₓ, to the state where a single cell that happens to have the lowest voltage is sitting at Vₘᵢₙ. Ideally, this should be the same cell, as the pack capacity is then determined by the cell with the lowest actual capacity. In practice, it will be determined by different cells, as over time the cells will be sitting at different voltages due to self-discharge. An out-of-balance pack will appear to have a lower useable capacity, even though each individual cell will have a higher capacity.

Therefore, cell balancing is needed to assist in keeping the cells of the battery pack balanced with respect to charge, voltage and/or state of charge. During cell balancing, it is useful to know current values for voltage, current and/or state of charge values of the cells to be balanced to properly monitor and control the balancing. Typical battery systems, such as the system illustrated in FIG. 1 are unable to monitor the cells during the balancing process and instead must periodically stop the cell balancing procedure in order to obtain voltage, current and state of charge measurements.

There are two types of balancing architecture. The first, which is the subject of this disclosure, is passive balancing. In passive balancing, a cell is identified that has a high state of charge, or cell voltage, relative to the other cells in the battery pack. An electrical load (e.g., a resistor) is then switched into place across the cell, providing a discharge path for that cell, and no others. Excess charge or energy in the cell is dissipated by the electrical load (e.g., as heat in a resistor) until the cell has the same state of charge, or voltage as the others, and is therefore in balance. Typical balance currents are less than an ampere, usually 100 mA or similar. This is a simple, low-cost method, but it wastes energy as charges are dissipated.

An alternative method is active balancing. Active balancing identifies a cell or group of cells with a high state of charge and a cell or group of cells with a low state of charge. An active circuit transfers the excess energy from the high cell(s) to the low cell(s). There are many active balancing architectures, some using switched capacitors, others using inductors or transformers, but all have in common that the excess energy is moved and not dissipated. Active balancing is relatively complex and expensive to implement compared to passive balancing. Active balancing is generally only used in applications that require high balancing currents, such as many amps or tens of amps. While high currents can be achieved with passive balancing, the wasted energy becomes problematic, and the heat generated in a balancing resistor for example needs to be removed. Active balancing always requires one or more source cells and one or more target cells. Active balancing cannot operate on a single cell in isolation.

In both cases, the balancing circuit is typically located at a distance from the cells, on a centralised board. Connections are made from this board to the individual cells, over which the cell voltage is measured, and the balance current drawn. As will be seen, drawing the balance current over the voltage sense wires leads to measurement errors, and for this reason, balancing is often switched off while the voltage is being measured. This is inefficient and adds complexity. The alternative is to use separate measurement connections and balance connections, however, this operation is costly.

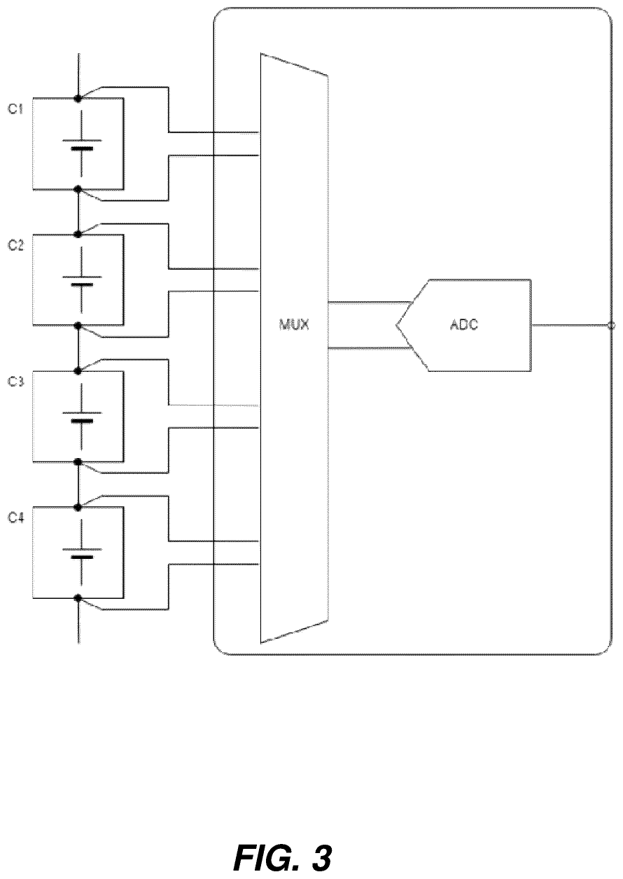

One reason the system of FIG. 1 is unable to obtain measurements during cell balancing is the hardware architecture. Specifically, as shown in FIG. 1, each cell C1-C8 makes two wired connections with the CMD 180. Thus, for a battery module featuring eight cells, sixteen wired connections to the CMD must be made. In order to obtain measurements during balancing for such a configuration, a multiplexer (MUX) would be required, as shown in FIG. 3. However, as the number of cells, modules and battery packs increase within a single system, the hardware configuration of such a solution becomes complex.

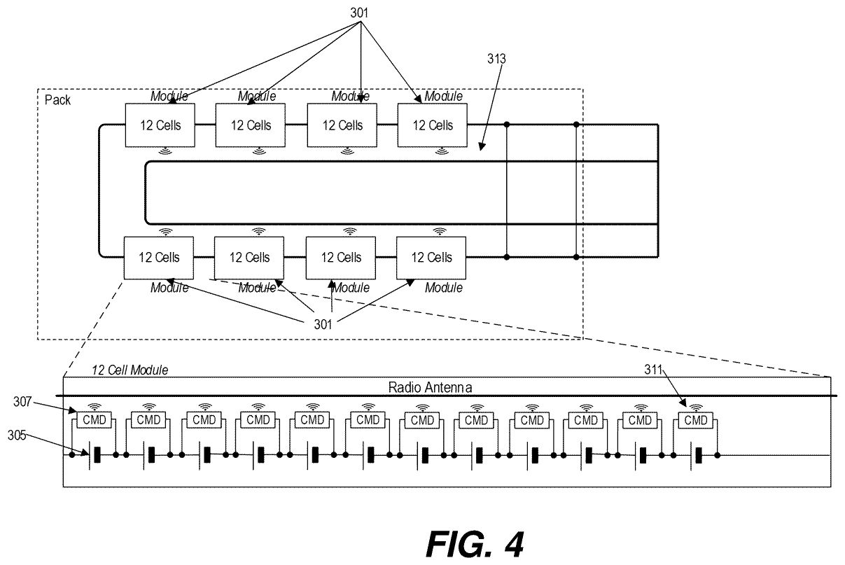

According to the example embodiments, a system for cell balancing which allows for monitoring and measurement taking to occur during the cell balancing procedure is provided. An example of such a system is illustrated in FIG. 4. The system of FIG. 4 illustrates a battery pack featuring eight battery modules 301, with each module featuring twelve battery cells. Each battery cell 305 is in communication with a respective CMD 307 which provides various measurements for the associated cell. All the CMDs 307 are in communication with each other and a central controller via a radio antenna 311 and a wireless communications bus 313. It is understood that, as described herein, according to other example embodiments, each module features another number of battery cells, each battery cell being in communication with a respective CMD. According to yet another example embodiment, some of the modules may feature a different number of battery cells than the other modules of the same system.

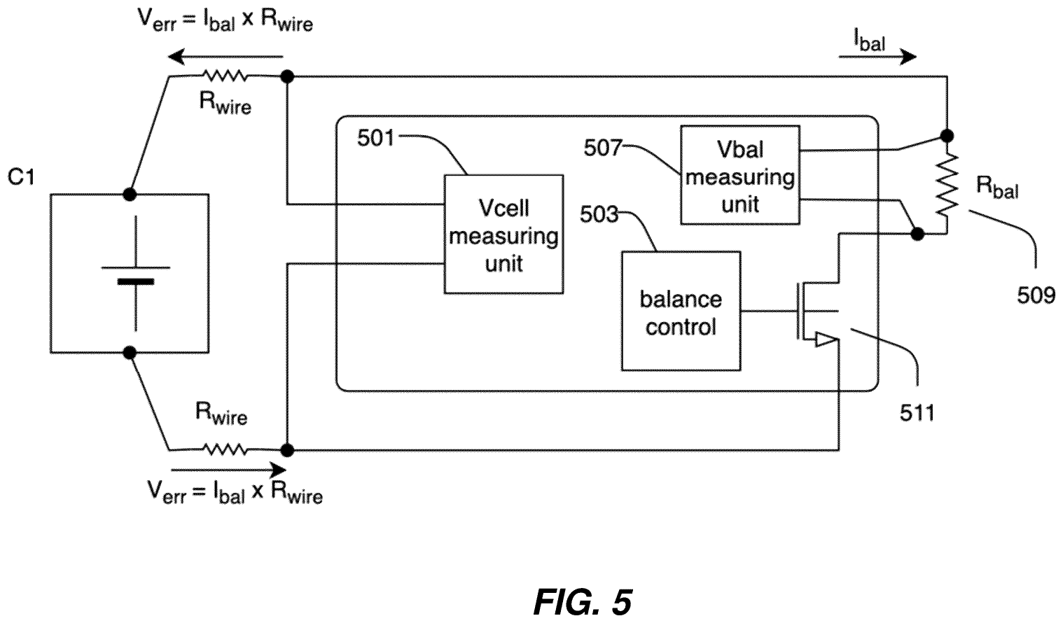

FIG. 5 illustrates an example configuration of the CMD, according to some of the example embodiments. The CMD comprises a measuring unit 501. The measuring unit may comprise any number or type of sensor used in monitoring an electric battery system. Examples of such sensors may include temperature, voltage, and current based sensors. In FIG. 5, measuring unit 501 is configured to measure the cell voltage.

The CMD may also comprise a balancing control unit 503 which may be a controller or processor configured to balance the cell associated with the respective CMD if the said cell is identified as needing cell balancing. A field effect transistor (FET) 505 is in communication with the balancing control unit 503. The CMD of FIG. 5 further comprises a balance resistor R_{bal} 509 which is configured to be switched by the balancing control unit 503. A cell-balancing current I_{bal} and a cell-balancing voltage V_{b}aa (voltage across balance resistor 509) may be measured via the balance resistor R_{bal}, for example, via a measuring unit 507 separate from the balancing control unit 503. Accordingly, the CMD is able to control cell balancing independently and simultaneously measure a cell-balancing current I_{bal} and/or a cell-balancing voltage V_{bal}. The CMD further comprises parasitic resistance R_{wire} in the connections situated between the CMD and each respective cell where a cell-level voltage measurement V_{cell} may be obtained.

According to some of the example embodiments, the CMD of FIG. 5 may be configured to perform passive balancing which involves decreasing the charging current, or increasing the discharge current, on an individual cell, such that a cell at a low voltage relative to other cells in the pack is charged at a lower rate, or a cell at a high voltage relative to the other cells in the pack is discharged at a higher rate. For example, this brings the cell's voltage down faster than the other cells that are not being balanced. By measuring the cell voltage and determining which cells are at a high potential relative to the others, the cells that need balancing can be selected. The CMD illustrated in FIG. 5 places the passive balance circuit at each battery cell, reducing the cost of the connections and allowing balancing to occur during cell voltage measurements.

The decrease in charge current, or increase in discharge current, may be achieved by drawing a current that bypasses the cell. This may be done by switching a resistive load in parallel with the cell, namely, R_{bal}. Some of the cell charge current then bypasses the cell by flowing through the balance resistor on charge, or, the cell discharge current is increased by the additional current flowing through the balance resistor. According to some of the example embodiments, balance resistor (R_{bal}) may be a simple resistor, or a current source of some kind (current source connected MOSFET), or a switch operating as a pulse width modulated load, or some combination thereof.

Because of the cell-level voltage changing during the balancing procedure, a voltage error (Vₑᵣᵣ) will not be constant. However, as each cell is individually monitored during cell balancing, the voltage error Vₑᵣᵣ may be continuously calculated and compensated for. In FIG. 5, a second measuring unit 507 measures the voltage V_{bal} across the balancing resistor R_{bal}. The value of R_{bal} will be known by design. The balancing current can then be calculated I_{bal}=V_{bal}/R_{bal}. For example, the voltage error is equal to the balancing current over the parasitic resistance over the connection with the individual cell (Vₑᵣᵣ=R_{wire}×I_{bal}). Thus, by knowing the voltage error Vₑᵣᵣ, the cell-level voltage measurement may be compensated by taking into account the known error, specifically, V_{cell_compensated}=Vₑᵣᵣ+V_{cell}. It should be noted, in prior art systems (e.g., the system of FIG. 1), cell balancing would need to be paused in order to allow for the voltage error to return to zero before measuring the cell-level voltage. Such means of providing cell balancing is not efficient. It should also be noted that the value for R_{wire} can be determined by measuring the change in voltage V_{cell} whilst switching current I_{bal} on and off under controlled conditions. The value for I_{bal} is useful for compensating for Vₑᵣᵣ, but also for calculating the balancing power and energy.

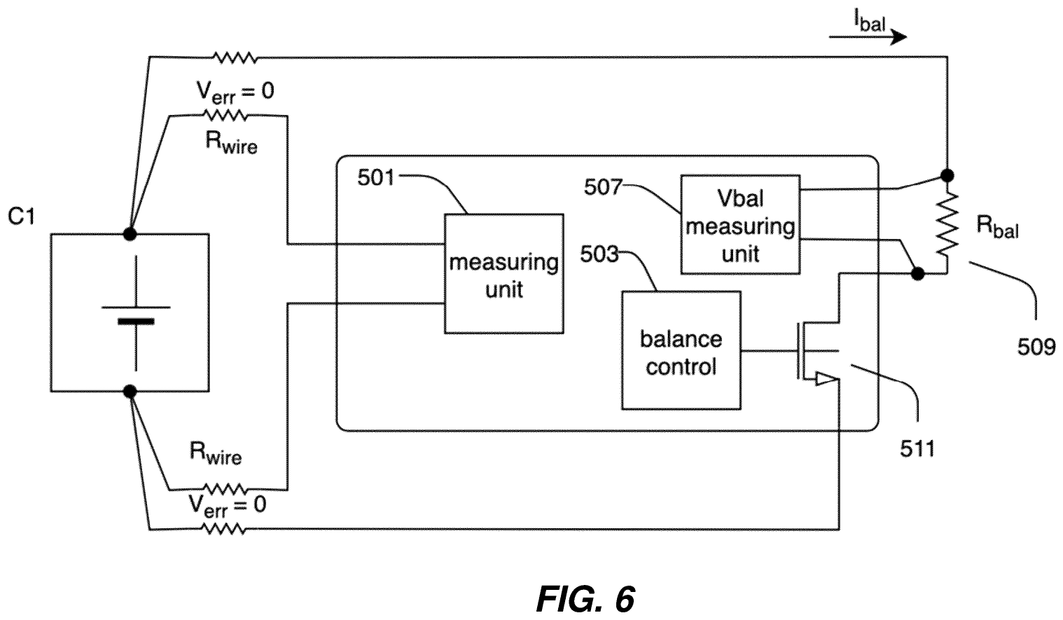

FIG. 6 illustrates another example configuration of the CMD, according to some of the example embodiments. The CMD configuration of FIG. 6 includes a kelvin connection between the CMD and the respective battery cell, where four connections are provided. In such a configuration, the cell-balancing current I_{bal} is not affected by the parasitic resistance, R_{wire} Thus, this removes the voltage and current fluctuation and therefore, it is possible to eliminate the voltage error (Vₑᵣᵣ=0), at the cost that the balance resistor cannot share connections with 501.

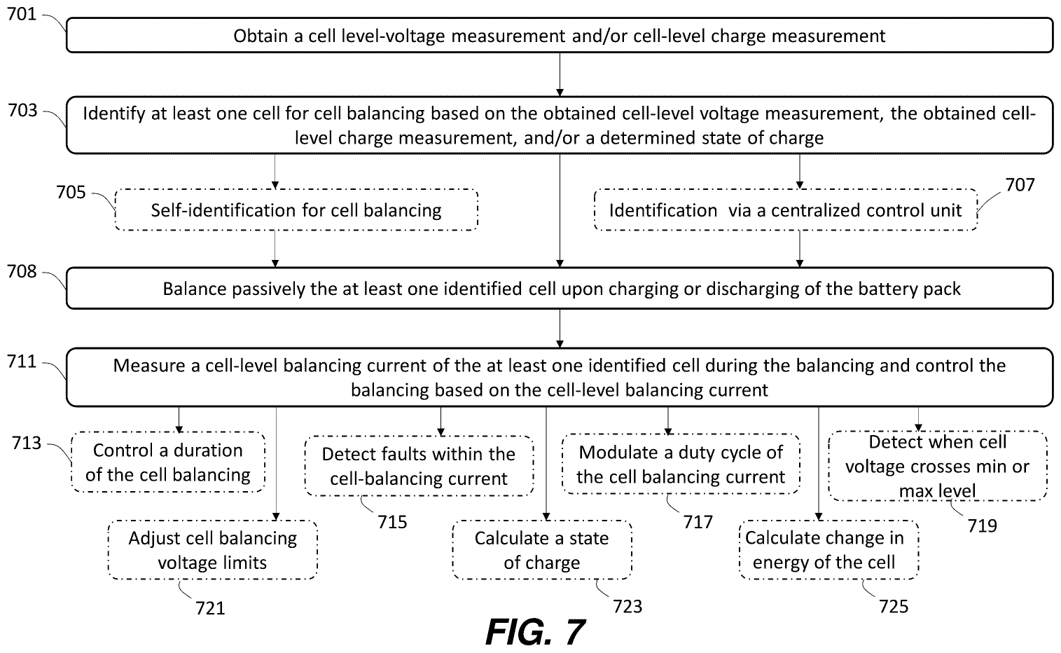

FIG. 7 is a flow diagram depicting example operations which may be taken by the CMD of FIGS. 5 and 6 as described herein in providing cell balancing for a respective cell in a battery pack. It should be appreciated that FIG. 7 comprises some operations which are illustrated with a solid border and some operations which are illustrated with a dashed border. The operations which are comprised in a solid border are operations which are comprised in the broadest example embodiments. The operations which are comprised in the dashed border are example embodiments which may be comprised in, or a part of, or are further operations which may be taken in addition to the operations of the broader example embodiments. It should also be appreciated that the actions may be performed in any order and any combination.

### Operation 701

According to the example embodiments presented herein, the measuring unit 501 is configured to measure continuously, with at least one sensor comprised in (or in connection with) the CMD, or within the measuring unit itself, at least one of a cell-voltage measurement (V_{cell}) or a cell-level charge measurement (I_{cell}) of the respective cell. As illustrated in FIGS. 5 and 6, such measurements may be obtained via the parasitic connection resistance in direct communication with respective cell, R_{wire}. As illustrated in FIG. 5 such measurements may be obtained via a connection with the respective cell common to the balance current path. The parasitic connection resistance R_{wire} develops a measurement error Verr due to the balance current I_{bal} flowing through it. As illustrated in FIG. 6, such measurement may be obtained by a connection with the respective cell via a separate path to that used by the balance current. In this case, the voltage error on the measurement is reduced to near zero.

### Operation 703

According to the example embodiments, the balancing control unit 503 is configured to identify at least one cell of the plurality of battery cells to undergo cell balancing based on at least one of the respective cell-level voltage measurement (V_{cell}), cell-level charge measurement (I_{cell}) or a determined cell-level state of charge. The cell-level state of charge may be calculated based on the cell-level voltage measurement and/or the cell-level charge measurement.

### Example Operation 705

According to some of the example embodiments, the balancing control unit 503 may be configured to identify the at least one cell of the plurality of battery cells based on a self-identification. Specifically, a CMD may be able to determine the need for cell-balancing an associated cell without receiving explicit instructions to do so.

According to some of the example embodiments, a balancing control unit 503 may self-identify a need for cell balancing based on a cell-level voltage, charge or state of charge, of a respective cell, surpassing a deliberate voltage or charge target threshold. A deliberate voltage threshold may be used in top balancing where a cell is deliberately charged, thereby surpassing a deliberate voltage threshold, to initiate the balancing process. A charge target threshold may be used to determine if an amount of charge of a respective cell has drifted above a level of charge deemed acceptable for the cells of the battery pack. If so, top balancing may be employed.

According to some of the example embodiments, balancing control unit 503 may self-identify the need for cell balancing based on a cell-level voltage, charge or state of charge not falling within a predefined bottom balancing threshold or voltage or charge. In this case, the measured parameters of the respective cell fall below the acceptable level associated with the cells of the battery pack. In this instance, balancing is provided via bottom balancing.

According to some of the example embodiments, the balancing control unit 503 may self-identify based on a cell-level voltage, charge or state of charge difference of the respective cell in relation to at least one other cell within the battery pack. In such example embodiments, a CMD may have knowledge of measurements taken by one or more other CMDs within the battery pack. According to some of the example embodiments, the CMDs may be in communication with one another via the wireless communications bus and/or each CMD may report its respective measurements and have access to a centralized location for storing obtained measurements. Thus, once a CMD detects obtained measurements of its respective cell differ with respect to the measurements obtain by a different CMD, in relation to another cell, within the battery pack, cell balancing may be initiated, for example, based on the size of the measurement difference. An example of an acceptable level of measurement difference between different cells may be 50 mV, where lower values would result in balancing occurring more frequently and higher values may reduce the effective capacity of the battery pack.

### Example Operation 707

According to some of the example embodiments, the balancing control unit 503 may be configured to identify the at least one cell for cell balancing via a centralized control unit. According to such embodiments, the CMD may transmit, via a respective radio antenna, the cell-level voltage, state of charge, and/or charge measurement, to the centralized control unit via the wireless communications bus. The CMD may also receive, from the centralized control unit, instructions to cell balance its associated cell based on the respective the cell-level voltage, state of charge, and/or charge measurement.

### Operation 708

The example embodiments further comprise balancing passively the at least one identified cell upon charging or discharging of the battery pack. Passive balancing of the at least one cell may be achieved by using a passive balancing architecture (charge dissipated via an electrical load) as described above. For example, in the case of top balancing, balancing will be provided via a reduction in the effective charge rate on the cell being balanced. In the case of bottom balancing, balancing is provided via an increase in the effective discharge rate of the cell being balanced, of the identified cell.

### Operation 711

The example embodiments further comprise measuring a cell-balancing current (I_{bal}) of the at least one identified cell during balancing and controlling the balancing based on at least one of the measured cell-level balancing current, the measured cell-level voltage, or the measured cell-level charge. Thus, in contrast to prior art systems where the balancing process must be suspended in order to properly monitor the balancing, the example embodiments provided herein provide the possibility of monitoring the balancing process continuously without suspending cell balancing. For example, cell-balancing current (I_{bal}) is measured via resistor R_{bal}. In accordance with the exemplary embodiments and as shown in FIG. 5 or 6, cell-level properties (voltage, current or both) measurement, balancing control, and balancing current measurement are performed by three separate units included in the CMD (respectively measuring unit 501, balance control 503 and V_{bal} measuring unit 507), thereby allowing these three processes to be performed simultaneously. In particular, cell-level properties can be measured continuously at any stage of the balancing process, without interruption, and independently of the balancing process control. The three units can work in unison by communicating with each other.

### Example Operation 713

According to some of the example embodiments, the balancing control unit 503 may be configured to control a duration of the balancing of the at least one identified cell. Specifically, by monitoring the cell-level balancing current, a rate of discharge and/or charging may be evaluated to ensure balancing is performed such that the balanced cell will reach the desired level of charge.

### Example Operation 715

According to some of the example embodiments the balancing control unit 503 may be configured to control the cell balancing by detecting faults within cell-balancing current I_{bal}. Specifically, the balancing control unit 503 may detect when the cell balancing current has surpassed a maximum allowable level to ensure proper operation of the battery cell. Or, there may be a maximum power that can safely be dissipated on the battery cell, or a maximum temperature it can be allowed to reach. In each case, the balancing current I_{bal} may be reduced or switched off to avoid a fault.

### Example Operation 717

According to some of the example embodiments, the balancing control unit 503 may also be configured to modulate cell balancing current I_{bal}. As explained above, passive balancing decreases a charging current, or increases a discharge current, in order to increase the rate at which a cell's voltage is adjusted during the balancing. The modulating of the cell balancing current aids in maintaining a desired average current level to achieve the desired balancing of the cell.

### Example Operation 719

According to some of the example embodiments, the balancing control unit 503 is configured to control the balancing based on the cell-level voltage (V_{cell}) measured by measuring unit 501 during the balancing of the at least one identified cell and knows the value of the cell-level voltage. In such embodiments, balancing control unit 503 may also be configured to detect when the measured cell-level voltage is below a minimal cell-level voltage for maintaining safe cell operation, or above a maximum safe voltage. However, the true V_{cell} voltage may be higher than measured when balancing, due to the error voltage across R_{wire} (as explained in relation to FIG. 5). Operation 719, by knowing the balance current I_{bal}, can compensate for the error voltage, allowing a better judgement of when a threshold is crossed.

### Example Operation 721

According to some of the example embodiments, the balancing control unit 503, while knowing the measured cell-level voltage during the balancing of the at least one identified call, is further configured to adjust cell balancing voltage limits during the balancing. Every cell has an effective internal series resistance Rᵢₙₜₑᵣₙₐₗ. The switching on of balance current I_{bal} may cause a voltage drop at the cell terminals of I_{bal}×Rᵢₙₜₑᵣₙₐₗ. A cell may be determined to require balancing at, for example, operation 711. However, when the balancing current is turned on, then the cell voltage will drop, which may turn balancing off again.

Example operation 721 is the CMD, knowing the balance current I_{bal}, adjusting the voltage threshold such that it determines the need to balance on a first threshold, but determines the need to continue balancing on a second voltage threshold limit. This second voltage threshold limit may be adjusted during the process in response to the balance current as it varies.

### Example Operation 723

According to some of the example embodiments, the balancing control unit 503, while obtaining measurements of the cell-level balancing current and the cell-level voltage, is configured to calculate a state of charge during the cell balancing. In contrast to prior art systems which require a suspension of the balancing procedure in order to determine the state of charge, the example embodiments provide a means of determining and monitoring the state of charge throughout the balancing process. This then makes it possible to control (e.g., adjust the rate of charge or discharge) the balancing process more efficiently and accurately, for example, using state of charge determined or monitored in real time.

### Example Operation 725

According to some of the example embodiments, the balancing control unit 503 may be further configured to calculate a change in the energy of the respective cell undergoing cell balancing by integration of a balancing power over time. Balancing power may be obtained from the measured cell-level balancing current (I_{bal}) and the measured cell-level balancing voltage (V_{cell}). An example of a calculated energy change of the cell is a cell's power integrated over time, expressed in Watt-hours (Wh) or Joules (J). Monitoring of such changes assist in ensuring the cell is balanced to a proper level.

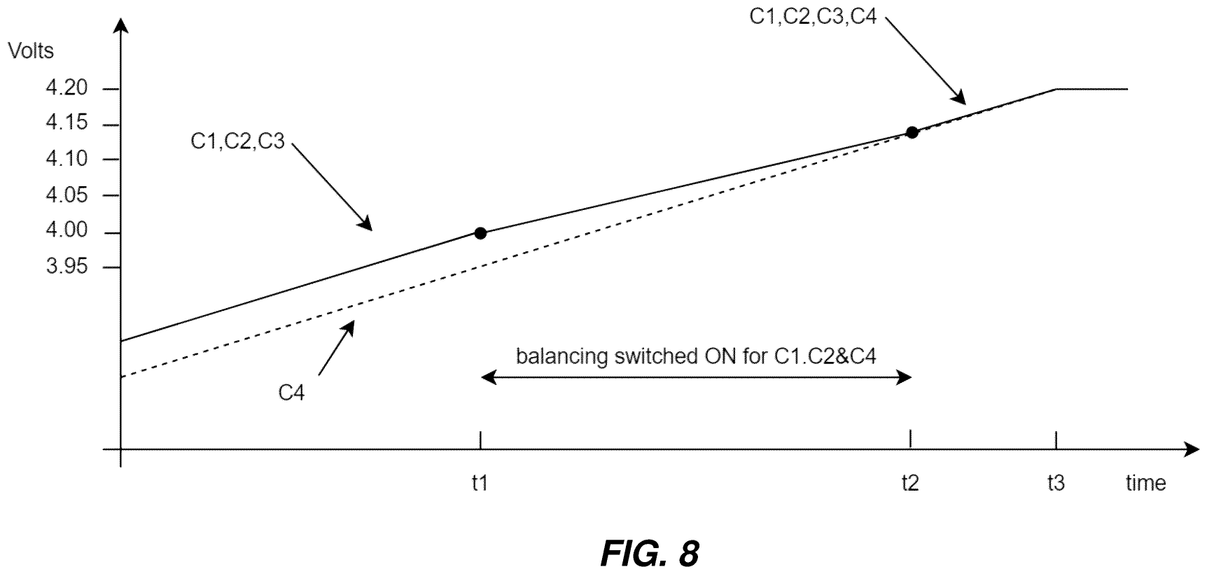

FIG. 8 illustrates a working example of the monitoring and control of a cell top balancing process, wherein balancing occurs when individual cells are balanced as they near full charge (or full capacity). Take a set of 4 cells C1, C2, C3 and C4, which are connected in series. Each cell has a nominal capacity 1 Amp-hr (1 Ah). Each cell has a measured voltage V1, V2, V3 and V4. In the present example, the maximum allowed voltage on any cell is 4.2V. The minimum allowed voltage is 3.0V. Using the example embodiments presented herein, the voltage on each cell may be continuously measured.

The cells are placed on a charger circuit, and a 1000 mA current is fed through the cells. After some time t1, V1, V2 and V3 are all at 4.00V. This voltage equates to an SOC of 95%. V4 though sits at 3.95V. This is because C4 has suffered excess self-discharge because it has been, for example, at a higher temperature than the other cells, and the pack has not been balanced. This voltage equates to a SOC of 93%. Thus, cell C4 is 2% of 1 Ah=20 mAh lower charge than the other cells. Each cell has a 40Ω balance resistor which can be switched on and off by a MOSFET.

Switching the balance resistor (R_{bal}) on, when the cell voltage is 4.00V, this will cause a 100 mA current to flow. This 100 mA current bypasses the cell, reducing the charge current to that cell from 1000 mA to 900 mA. In order to balance the four cells, the balance resistor on C1, C2 and C3 is switched on. Cells C1, C2 and C3 are now charging at 900 mA. Cell C4 continues to charge at 1000 mA. All four cells continue to charge towards their maximum allowed voltage of 4.20V.

C1, C2 and C3 are now charging at only 900 mA. 100 mA is bypassed around each cell, C₁-C₃. Because they are at 95% SOC, they require 5% of 1 Ah=50 mAh to reach full charge. This will take 50 mAh×60×60/900 mA=200 seconds. Because C4 is charging 100 mA faster than C1, C2 and C3, it will reach full charge in 50 mAh×60×60/1000 mA=180 seconds. At time t2, before 180 seconds have elapsed, at the cell voltage may be identical at 4.15V. At this time, the balancing is stopped as all cells are now in balance. Charging continues with all cells at 1000 mA until t3, when the maximum allowed voltage of 4.2V is reached. At this time charging must stop. If any cells reach the maximum allowed voltage of 4.2V before balancing is complete, then charging and balancing terminate.

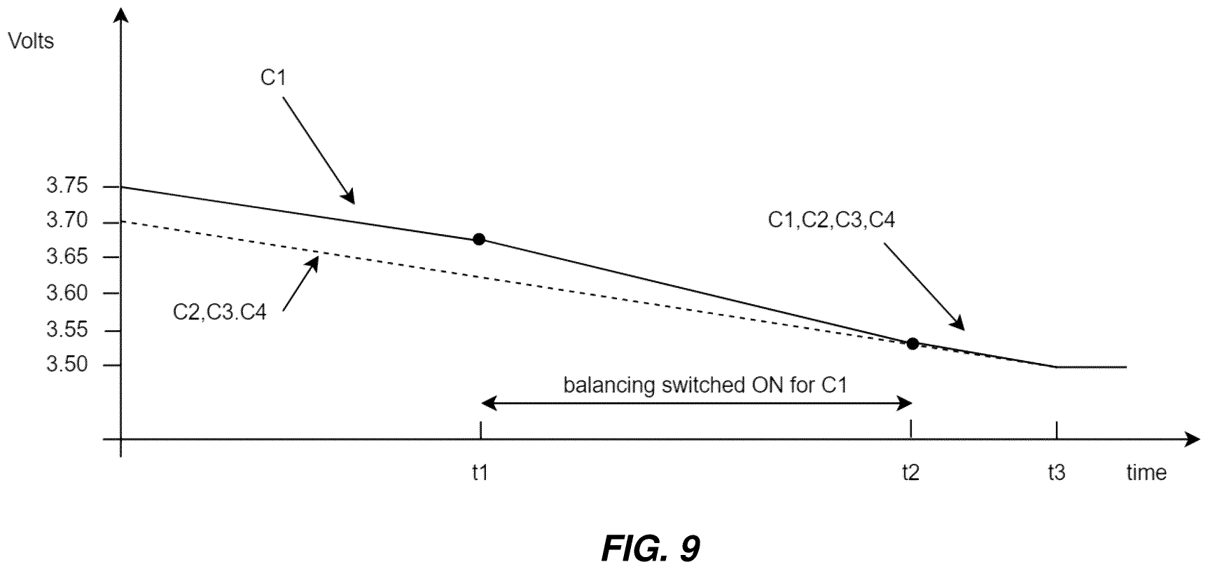

FIG. 9 illustrates a working example of the monitoring and control of a cell bottom balancing process. At t1, it is determined that C1 has a higher cell voltage than the others, so balancing is turned on. C1 is now discharging at 1100 mA, until t2 when the voltages are all equal. Discharge continues until t3, when it must stop as the minimum allowed voltage is reached. If any cells reach the minimum allowed voltage of 3.5V before balancing is complete, then discharging and balancing terminates.

When balancing is on, the balancing current will cause a shift in the cell voltage. For instance, in the top balancing example case of FIG. 8, the reduction in the charge current on C1, C2, and C3 from 1000 mA to 900 mA will cause the cell voltage to increase by a small amount. If charging was to be terminated when V1 (or V2, V3) hits the allowed maximum, and C1, C2, and C3 were still balancing, such that C4 was still charging at the higher rate, then on termination of charging, C4 would increase in voltage by a larger amount than C1, C2, and C3. In practice, the charger circuit would go into a constant voltage—constant current charging mode, whereby the charge current is gradually reduced while keeping the cell voltage nearly constant. But the charging current interferes with this, since on removal of balancing, C4 will change by a different amount to C1, C2, and C3. This makes the charge and balance process less precise.

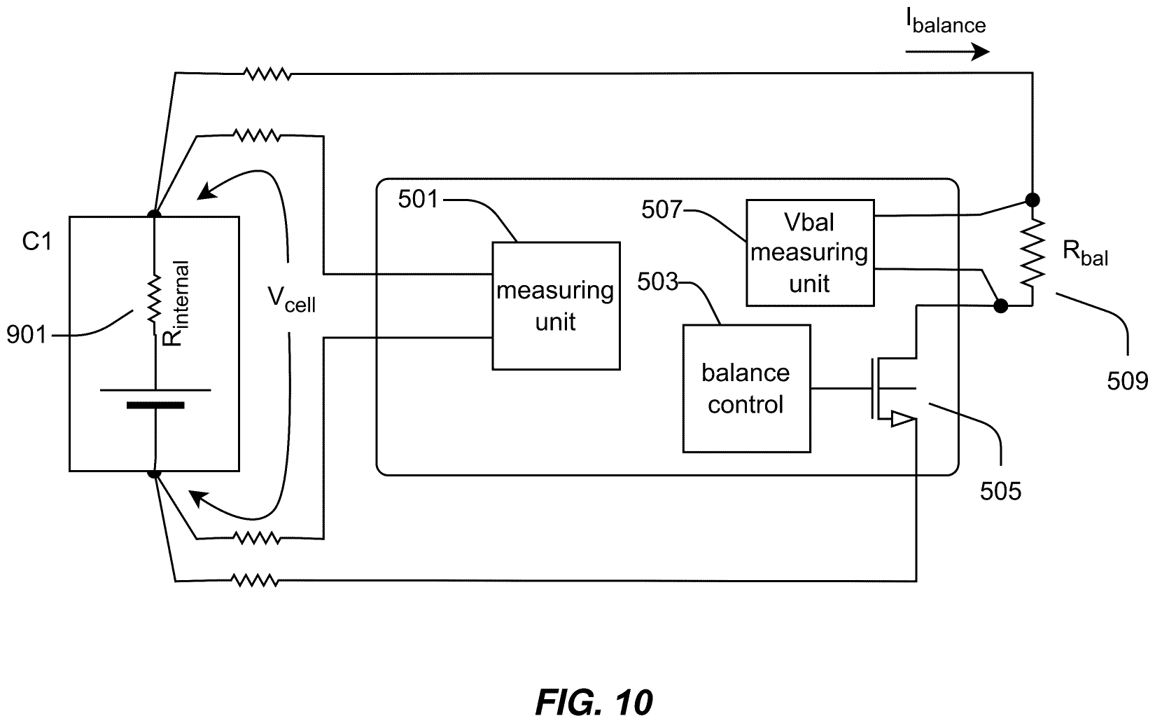

Another aspect arises from the ability of the example embodiments to simultaneously measure cell-level properties and balance current, namely the determination of the internal resistance of the cell Rᵢₙₜₑᵣₙₐₗ. FIG. 10 illustrates the CMD of FIG. 6 further including an internal resistance Rᵢₙₜₑᵣₙₐₗ 901 of the connected battery cell, according to some of the example embodiments. When the balancing is activated, there is a small drop in the cell voltage V_{cell} due to the cell's internal resistance Rᵢₙₜₑᵣₙₐₗ. This voltage change is small, as the value of Rᵢₙₜₑᵣₙₐₗ may only be 1 mΩ or less, and the balancing current I_{bal} only be 100 mA, such that the voltage drop is 100 V according to the usual Ohms law. The cell voltage V_{cell} and the balancing current I_{bal} are measured simultaneously by measuring unit 501 and V_{bal} measuring unit 507 or close enough in time for noise to be correlated, and therefore removed by processing. In the context of this description, balancing activation/deactivation refers to connecting/disconnecting a load such as the balancing resistor 509 to the battery cell terminal. For example, by controlling the gate voltage of transistor 505, it may act as a switch and therefore connecting or disconnecting the balancing resistor to the battery cell terminal.

Thus, unlike the prior art system, the embodiments presented herein allow the internal resistance to be measured for each individual cell without significantly altering the state of charge. In fact, in conventional systems, the internal resistance is usually determined at the scale of the battery pack by measuring the open circuit voltage of the battery pack and then connecting a load to it, an option that requires large stimulus currents. This option significantly alters the state of charge of the battery pack and only allows the determination of an average internal resistance of the battery cells comprised in the battery pack, and requires knowledge of the architecture of the battery pack (how many battery cells are connected in series/parallel).

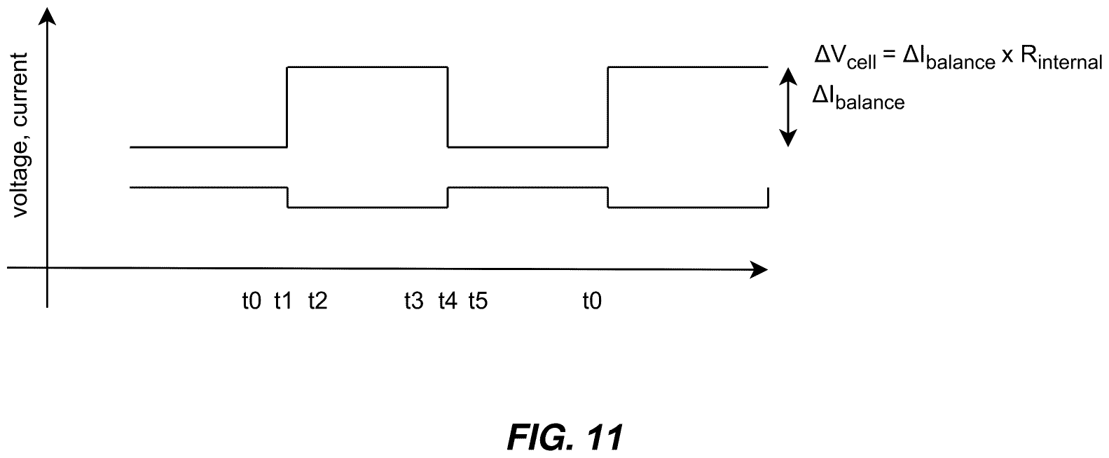

FIG. 11 illustrates an exemplary evolution of cell voltage V_{cell} and balancing current I_{bal} over time during measurement of the internal resistance Rᵢₙₜₑᵣₙₐₗ of the battery cell shown in FIG. 10. Cell voltage V_{cell} and balancing current I_{bal} are measured at t0. In this state, the balancing current I_{bal} is expected to be zero as the balancing is deactivated, and V_{cell} is equal to the open circuit voltage since there is no load connected to the battery cell. Balance control 503 activates the balancing at t1, and a second measurement of cell voltage V_{cell} and balancing current I_{bal} is then made at t2. These measurements can be used to calculate Rᵢₙₜₑᵣₙₐₗ 901. An example of the calculation is as follows. ΔV_{cell-1}=V_{cell-t2}−V_{cell-t0} (difference in the measured cell-level voltage V_{cell} before and after activating the balancing), and similarly ΔI_{bal-1}=I_{bal-t2}−I_{bal-t0} (difference in the measured cell-level balancing current I_{bal} before and after activating the balancing). The value of the internal resistance can be calculated from Rᵢₙₜₑᵣₙₐₗ=ΔV_{cell-1}/ΔI_{bal-1}|.

The accuracy of the internal resistance measurement can be improved by performing a second set of measurements, at a later time, when the balancing is deactivated. For example, as shown in FIG. 11, another sample is taken a little later, at t3, balancing is deactivated at t4, and another sample is taken at t5. The actual period is not significant, but if it is much less than a second, many measurement cycles can be taken before the balancing current significantly changes the cell state. Similarly, one may define ΔV_{cell-2}=V_{cell-t5}−V_{cell-t3} (difference in the measured cell-level voltage V_{cell} before and after deactivating the balancing) and ΔI_{bal-2}=I_{bal-t5}−I_{bal-t3} (difference in the measured cell-level balancing current I_{bal} before and after deactivating the balancing). The internal resistance can then be calculated according to Rᵢₙₜₑᵣₙₐₗ=(ΔV_{cell-1}−ΔV_{cell-2})/(ΔI_{bal-1}−ΔI_{bal-2}). Several such measurement cycles (balancing activated/deactivated) may be made to improve the accuracy of the determination of the Rᵢₙₜₑᵣₙₐₗ value, for example by averaging the measurements. The actual frequency of these measurement cycles may be on the order of a few Hertz.

At such a frequency, the total time required to determine the value of the internal resistance by averaging the results obtained over several measurement cycles is in the order of tens of seconds. For example, averaging over 40 cycles at a frequency of 2 Hz would take only 20 seconds. This time may be negligible compared to the time required for the entire balancing process, which may take up to several hours. Accordingly, in some embodiments, the determination of the internal resistance by repeating the measurement cycles described above may be carried out at different stages of the balancing process without significantly disturbing it. This makes it possible to follow the evolution of the value of the internal resistance at different stages of the balancing. The different stages of the balancing process correspond to different values for cell voltage and/or state of charge, so it is further possible to map the value of the internal resistance for different cell as a function of these parameters. Alternatively, it is possible to obtain the value of the internal resistance of different cells at different temperatures by correlating the above measurements with those of a temperature sensor contained in different CMDs.

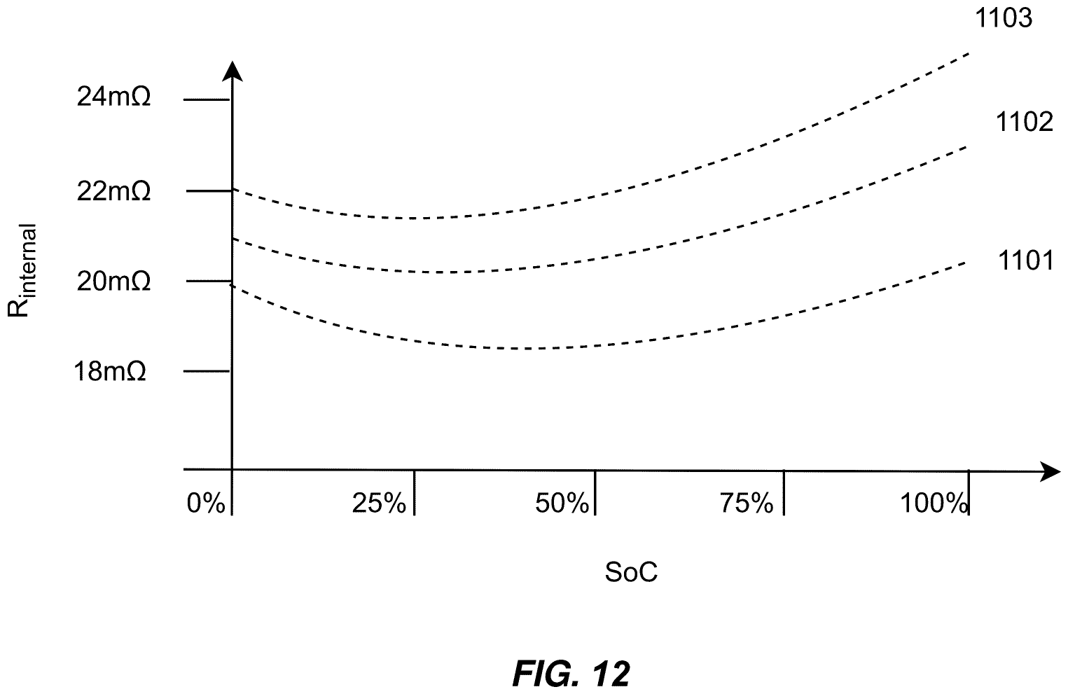

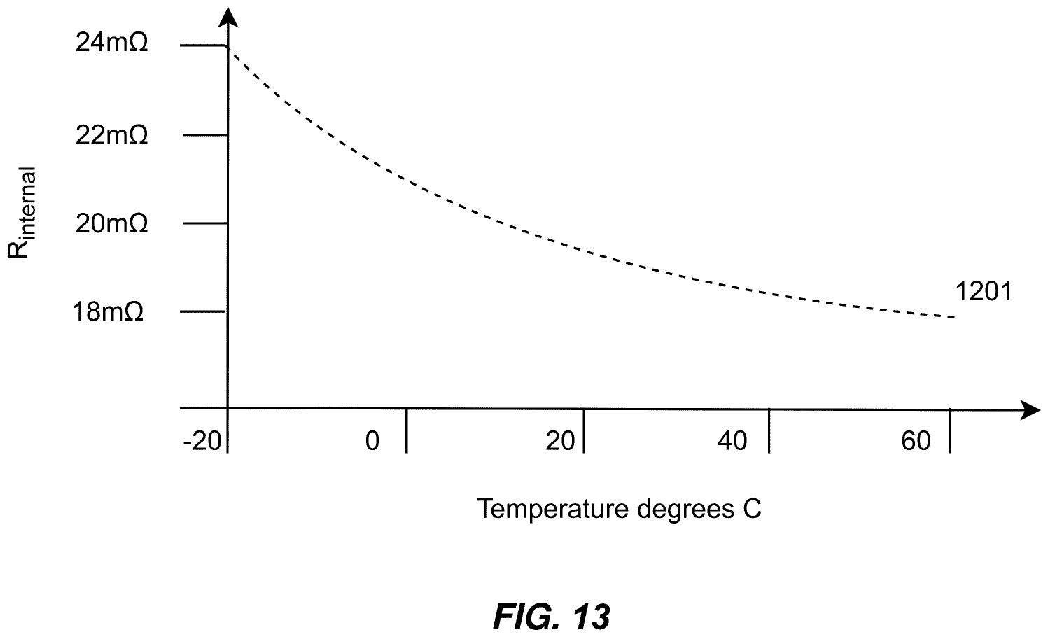

Many different physical and chemical mechanisms influence the value of the internal resistance of a battery cell. Examples of these mechanisms may include the resistivity of the electrodes or internal components, contact between these components, electrode surface area, electrolyte conductivity or ion mobility. As a result, the value of the internal resistance can be used to inform or improve estimates of the state of charge, state of health or state of available power of the battery cell. For example, algorithms can use the internal resistance value as part of their calculations, and a locally measured value is better than an assumed value. As a cell ages or degrades, the internal resistance typically increases. This is illustrated in FIG. 12, which shows characteristic changes in the internal resistance of a battery cell as a function of state of charge and cell age. The evolution of the internal resistance as a function of the state of charge for a newly fabricated cell is shown at 1101. As the cell ages, its internal resistance increases, as shown for 1102 and 1103. This increase is a valuable parameter to track. The state of available power is closely determined by the internal resistance, as the resistance increases the available power is lower. FIG. 13 illustrates characteristics changes in the internal resistance of a battery cell as a function of the temperature. Battery cell internal resistance is a decreasing function of the temperature (1201). Accordingly, the state of available power that a cell may deliver is a decreasing function of the temperature. By tracking the internal resistance with temperature, a better state of available power estimate may be made.

In some embodiments, each CMD may transmit periodically the determined value of the internal resistance of their respective cell to a central controller. The central controller may therefore monitor the evolution of the internal resistance of every battery cell comprised in the battery pack and further infer the state of charge, state of health or state of available power of the entire battery pack. Additionally, the controller can use the internal resistance information to identify a battery cell that may become faulty. For example, by identifying a battery cell with a much higher internal resistance than a determined average internal resistance of the battery cells comprised within the battery pack.

The description of the example embodiments provided herein has been presented for purposes of illustration. The description is not intended to be exhaustive or to limit example embodiments to the precise form disclosed, and modifications and variations are possible in light of the above teachings or may be acquired from practice of various alternatives or equivalents to the provided embodiments. The examples discussed herein were chosen and described in order to explain the principles and the nature of various example embodiments and their practical application to enable one skilled in the art to utilize the example embodiments in various manners and with various modifications as are suited to the particular use contemplated. The features of the embodiments described herein may be combined in all possible combinations of methods, apparatus, modules, systems, and computer program products. It should be appreciated that the example embodiments presented herein may be practised in any combination with each other.

It should be noted that the word “comprising” does not necessarily exclude the presence of other elements or steps than those listed and the words “a” or “an” preceding an element do not exclude the presence of a plurality of such elements. It should further be noted that any reference signs do not limit the scope of the claims, that the example embodiments may be implemented at least in part by means of both hardware and software, and that several “means”, “units” or “devices” may be represented by the same or functionally equivalent item of hardware.

The various example embodiments described herein are described in the general context of method steps or processes, which may be implemented in one aspect by a computer program product, embodied in a computer-readable medium or a non-transitory computer-readable medium, comprising computer-executable instructions, such as program code, executed by computers or one or more processors in networked environments. A computer-readable medium or a non-transitory computer readable medium may comprise removable and non-removable storage devices comprising, but not limited to, Read Only Memory (ROM), Random Access Memory (RAM), compact discs (CDs), digital versatile discs (DVD), flash memories, etc. Generally, program modules may comprise routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps or processes.

In the drawings and specifications, there have been disclosed example embodiments. However, many variations and modifications can be made to these embodiments. Accordingly, although specific terms are employed, they are used in a generic and descriptive sense only and not for purposes of limitation, the scope of the embodiments being defined by the following claims.

1. A method, in a battery pack of an electric battery system, for balancing cells within the battery pack with respect to voltage, charge and/or state of charge, wherein the electric battery system comprises at least one pack, each pack comprising a plurality of battery cells, wherein each battery cell is monitored via a cell monitoring device, CMD, which provides cell-level measurements, the method comprising:
measuring continuously, with at least one sensor comprised in a respective CMD, at least one of a cell-level voltage or a cell-level charge of the respective cell;
identifying at least one cell of the plurality of battery cells to undergo cell balancing based on at least one of the respective measured cell-level voltage, the measured cell-level charge or a determined cell-level state of charge;
balancing passively the at least one identified cell of the battery pack upon charging or discharging of the battery pack; and
measuring a cell-level balancing current of the at least one identified cell during the balancing, and controlling the balancing of the at least one identified cell based on at least one of the measured cell-level balancing current, the measured cell-level voltage or the measured cell-level charge.

2. The method of claim 1, wherein the identifying at least one cell further comprises self-identifying, via the CMD of each respective cell, based on:
a voltage, charge or state of charge, of a respective cell, surpassing a deliberate voltage or charge target threshold; or
a voltage, charge or state of charge not falling within a predefined bottom balancing threshold of voltage or charge; or
a voltage, charge or state of charge difference of a respective cell in relation to at least one other cell within the battery pack.

3. The method of claim 1, wherein the identifying at least one cell further comprises:
transmitting, via a radio antenna of each respective CMD, to a centralized control unit, the cell-level voltage, state of charge, and/or charge measurement via a wireless communications bus, wherein the centralized control unit is configured to control operations of the electric battery system; and
receiving, via the radio antenna of each respective CMD, from the centralized control unit, instructions to cell balance at least one cell based on the respective the cell-level voltage, state of charge, and/or charge measurement.

4. The method of any of claims 1-3, wherein the controlling the balancing based on at least one of the measured cell-level balancing current, the measured cell-level voltage or the cell-level charge further comprises:
controlling a duration of the balancing of the at least one identified cell; and/or
detecting faults within the cell-level balancing current; and/or
modulating a duty cycle of the cell-balancing current to obtain an average current.

5. The method of any of claims 1-4, wherein the controlling the balancing based on at least one of the measured cell-level balancing current, the measured cell-level voltage or the cell-level charge further comprises:
detecting when the measured cell-level voltage is below a minimal or maximum cell-level voltage for maintaining cell operation; and/or
adjusting cell balancing voltage limits during the balancing of the at least one identified cell.

6. The method of claims 4 or 5, wherein the controlling based on at least one of the measured cell-level balancing current, the measured cell-level voltage or the cell-level charge further comprises:
calculating a state of charge during the cell balancing of the identified cell; and/or
calculating a change in the energy of the respective cell undergoing cell balancing by integration of a balancing power over time, via calculation of the balancing power from the measured cell-level balancing current and the measured cell-level balancing voltage.

7. The method of any claims 4-6, wherein the controlling based on at least one of the measured cell-level balancing current, the measured cell-level voltage or the cell-level charge further comprises:
determining the internal resistance value of the at least one identified cell by:
deactivating the balancing process;
measuring the cell-level balancing current and the cell-level voltage before and after deactivating the balancing process;
activating a balancing process after a predetermined period of time;
measuring a cell-level balancing current and a cell-level voltage before and after activating the balancing process; and,
calculating the internal resistance value of the at least one battery cell based on the measured cell-level balancing current and the cell-level voltage.

8. A method, in a battery pack of an electric battery system, for determining battery cell internal resistance values, wherein the electric battery system comprises at least one pack, each pack comprising a plurality of battery cells, wherein each battery cell is characterized by an internal resistance value and monitored via a cell monitoring device, CMD, which provides cell-level measurements, the method comprising:
performing one or more measurement cycles on at least one battery cell, the measurement cycle comprising the steps of:
activating a balancing process;
measuring a cell-level balancing current and a cell-level voltage before and after activating the balancing process;
deactivating the balancing process after a first predetermined period of time;
measuring the cell-level balancing current and the cell-level voltage before and after deactivating the balancing process; and,
waiting a second predetermined period of time; and,
determining the internal resistance value of the at least one battery cell based on the measured cell-level balancing current and the cell-level voltage during the one or more measurement cycles.

9. The method of claim 8, wherein determining the internal resistance value of the at least one cell further comprises:
averaging a determined internal resistance value of the at least one cell based on the measured cell-level balancing current and the cell-level balancing voltage for each measurement cycle.

10. The method of any of claims 8 or 9 wherein performing one or more measurement cycles and determining the value of the internal resistance of the at least one cell is conducted at different time intervals or for different values of the voltage, state of charge, or temperature of the at least one cell, and the method further comprises:
mapping the value of the internal resistance as a function of time, cell voltage, state of charge or temperature.

11. The method of claim 10, further comprising:
using at least one map of the value of the internal resistance to estimate the state of charge, state of health or the state of available power of the at least one cell.

12. A battery pack comprising a plurality of cell monitoring devices, CMDs, for balancing cells within the battery pack with respect to voltage, charge and/or state of charge, wherein the battery pack comprises a plurality of battery cells, wherein each battery cell is monitored via a respective cell monitoring device, CMD, which provides cell-level measurements, wherein each CMD comprises:
a first measuring unit comprising at least one sensor configured to obtain a cell-level voltage measurement and/or a cell-level charge measurement of the respective cell;
a balance control unit configured to identify a respective cell for cell balancing based on the measured cell-level voltage, the measured cell-level charge and/or a determined state of charge of the respective cell and to balance passively the respective cell upon discharging or charging of the battery pack; and
a second measurement unit configured to measure a cell-level balancing current of the respective cell during the cell balancing,
wherein the balance control unit is further configured to control the cell balancing of the respective cell based on at least one of the measured cell-level balancing current, the measured cell-level voltage or the measured cell-level charge.

13. The battery pack of claim 12, wherein each CMD is further configured to perform the method of any one of claims 1-11.

14. The battery pack of any of claims 12 and 13, wherein the second measurement unit of each CMD is further configured to measure a cell-level balancing current by measuring a cell-level voltage during the cell balancing across a balancing resistor comprised within the CMD.

15. The battery pack of claim 14, wherein the balancing control unit of each CMD is further configured to calculate a cell voltage error based on the cell-level balancing current on a resistance of a common connection for a power supply of the respective CMD and the measuring unit of the respective CMD, from the respective cell to the respective CMD.

16. The battery back of claim 14, wherein at least one respective CMD comprises a separate connection for a power supply and the measuring unit via a kelvin connection between the at least one respective CMD and the respective cell.

17. The battery pack of any of claims 14-16, wherein each CMD further comprises a FET switch in connection with the balancing control unit.

18. A computer-readable medium storing instructions which, when executed by a processor of a respective cell monitoring device, CMD, of a battery pack, cause the respective CMD to execute the method according to any one of claims 1-11.
